(19) United States
(12) Patent Application Publication
(10) Pub. No.: US 2009/0179301 A1
(43) Pub. Date: Jul. 16, 2009

(54) FUSE HAVING CUTTING REGIONS AND FUSE SET STRUCTURE HAVING THE SAME

(75) Inventor: Keun Soo Song, Ichon-shi (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR INC., Ichon-shi (KR)

(21) Appl. No.: 12/346,587

(22) Filed: Dec. 30, 2008

(30) Foreign Application Priority Data
Jan. 16, 2008 (KR) 10-2008-0004850
Dec. 5, 2008 (KR) 10-2008-0122847

(51) Int. Cl. H01L 21/768

(52) U.S. Cl. 257/529; 365/96; 257/E21.592

(57) ABSTRACT

A fuse includes a main fuse region and a plurality of cutting regions extend from the main fuse region.

### CROSS-REFERENCES TO RELATED APPLICATION

The present application claims priority under 35 U.S.C. 119(a) to Korean application numbers 10-2008-0004850 and 10-2008-0122847, filed on Jan. 16, 2008 and Dec. 5, 2008, respectively, in the Korean Intellectual Property Office, which are incorporated herein by reference in its entirety as if set forth in full.

### BACKGROUND

1. Technical Field

The embodiments described herein relate to a fuse and a fuse set that includes the fuse, and more particularly, to a fuse having a plurality of cutting regions and a fuse set having the same.

2. Related Art

As the scaled sizes of semiconductor integrated circuits are reduced, the number of devices integrated in a single semiconductor chip has increased. Accordingly, the defect density of the devices has also increased, thereby lowering product yield of semiconductor devices. In extreme cases, a wafer used for manufacturing the semiconductor devices must be discarded.

In order to reduce the defect density, a redundancy circuit is used to exchange defective cells with extra replacement cells. In semiconductor memory devices, a redundancy circuit (or fuse circuit) can be installed corresponding to row interconnections, i.e., word lines, and column interconnections, i.e., bit lines, and may include a fuse set group for storing address information of the defective cell. The fuse set group includes a plurality of fuse set arrays having a plurality of fuses, wherein a program for each fuse set can be executed through a selective laser cutting.

FIG. 1 is a plan view of a conventional fuse set. In FIG. 1, the fuse set 40 includes a plurality of fuses 41 to 48 arranged in parallel to each other at regular intervals D. The fuses 41 to 48 are arranged in a line pattern and have substantially the same line width W and pitch P, wherein a region 50 is to be cut by a laser beam. Accordingly, the overall length of the fuse set 40 is 7D.

However, as the integration density of the semiconductor memory device increases, the number of semiconductor memory cells integrated in a bank increases and the size of the bank is reduced. However, the pitch P among the fuses 41 to 48 must be ensured to obtain a cutting pitch of the fuse set 40, thereby causing a difficulty in reducing the area of a circuit block including the fuse set 40.

In FIG. 1, since the pitch P among the fuses 41 to 48 is determined by the capacity of laser beam equipment used to fabricate the fuses, i.e., a laser alignment tolerance, if the pitch P among the fuses 41 to 48 is not ensured to correspond to the laser alignment tolerance, adjacent fuses 41 to 48 may be damaged when the fuses 41 to 48 are cut by the laser beam. Accordingly, a redundancy operation is performed on a normal memory cell, so that the defective cell is not replaced even if the defective cell is detected.

Thus, the area of the fuse set is not easily reduced in proportion to the integration density of the semiconductor integrated circuit. For this reason, an occupying area of the fuse set is gradually increased, thereby limiting the miniaturization of the semiconductor integration circuit.

### SUMMARY

A fuse and a fuse set having the same, in which the area of the fuse is reduced in proportion to the integration density of a semiconductor device, are described herein.

According to one aspect, a fuse includes a main fuse region and a plurality of cutting regions extend from the main fuse region.

In another aspect, a fuse set includes a plurality of first fuses, each including a main fuse region and a plurality of cutting regions extending from the main fuse region, wherein adjacent ones of the plurality of first fuses are invertedly turned about 180° (degrees) with respect to each other while maintaining a predetermined interval therebetween.

These and other features, aspects, and embodiments are described below in the section entitled “Detailed Description.”

### BRIEF DESCRIPTION OF THE DRAWINGS

Features, aspects, and other are described in conjunction with the attached drawings, in which:

FIG. 1 is a plan view of a conventional fuse set;

FIG. 2 is a plan view of an exemplary fuse according to one embodiment;

FIG. 3 is a plan view of an exemplary fuse set including the fuse of FIG. 2 according to one embodiment;

FIG. 4 is a plan view of another exemplary fuse according to another embodiment;

FIG. 5 is a plan view of another exemplary fuse set including the fuse of FIG. 4 according to another embodiment;

FIG. 6 is a plan view of another exemplary fuse according to another embodiment;

FIG. 7 is a plan view of another exemplary fuse set including the fuse of FIG. 6 according to another embodiment;

FIG. 8 is a plan view of another exemplary fuse according to another embodiment;

FIG. 9 is a plan view of another exemplary fuse set including the fuse of FIG. 8 according to another embodiment;

FIG. 10 is a plan view of another exemplary fuse according to another embodiment;

FIG. 11 is a plan view of another exemplary fuse set including the fuse of FIG. 10 according to another embodiment; and

FIGS. 12 and 13 are plan views of exemplary fuses and cutting regions according to different embodiments.

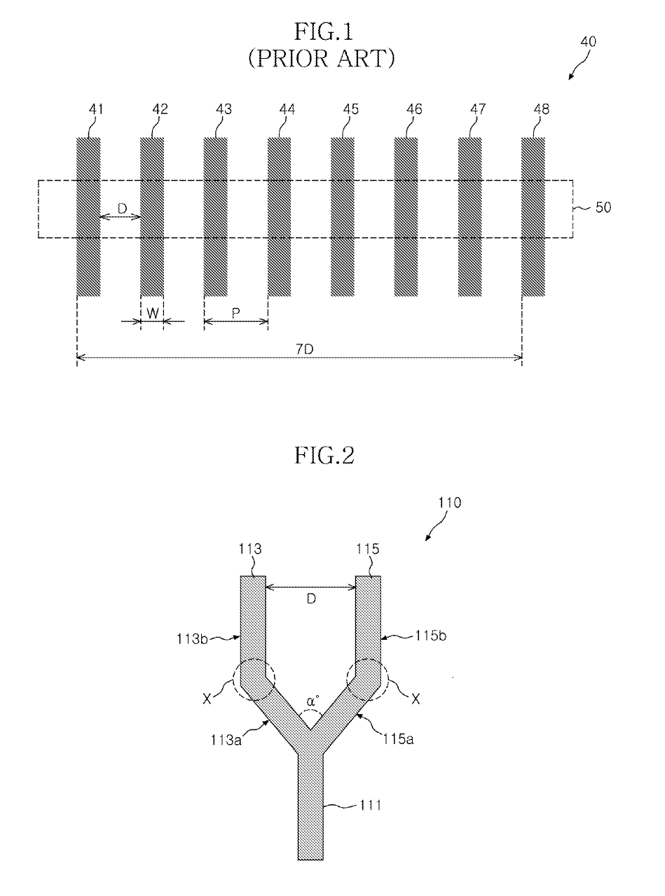

### DETAILED DESCRIPTION

FIG. 2 is a plan view of an exemplary fuse according to one embodiment. In FIG. 2, a fuse 110 may include a main fuse region 111 and a first cutting region 113 and a second cutting region 115.

The first and second cutting regions 113 and 115 can be configured to have a branch-off region that branches-off from an end of the main fuse region 111 at a predetermined angle α° and then extend substantially in parallel to each other. For example, the first and second cutting regions 113 and 115 can have a bending section X, and can be divided into first and second branch regions 113a and 115a and first and second parallel regions 113b and 115b, respectively, at the bending section X.

The first and second branch regions 113a and 115a can branch at the predetermined angle α° such that the first and second parallel regions 113b and 115b can be spaced apart from each other by a predetermined interval D. For example, the first and second branch regions 113a and 115a can obliquely extend from the main fuse region 111.

The interval D can be a minimum distance that does not cause adjacent first and second parallel regions 113b and 115b to exert influence on each other when a laser beam is radiated to cut the fuse 110. For example, the interval D can correspond to a laser alignment tolerance of a laser beam radiation apparatus used to cut the fuse 110.

The first and second cutting regions 113 and 115 can be configured to be substantially laterally symmetric to each other about the main fuse region 111. In addition, the fuse 110 may include a conductive layer, such as a polysilicon layer, that can be used to form a pattern in a semiconductor integrated circuit. Here, the main fuse region 111 and the first and second cutting regions 113 and 115 can be continuously formed and can have substantially the same line width.

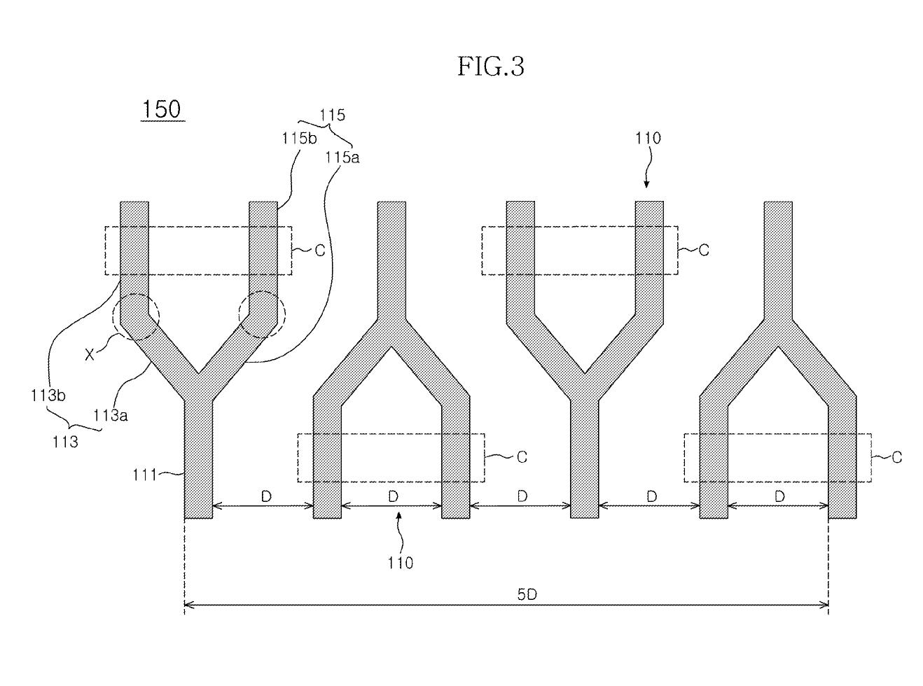

FIG. 3 is a plan view of an exemplary fuse set 150 including the fuse of FIG. 2 according to one embodiment. In FIG. 3, a plurality of fuses 110 having a plurality of cutting regions 113 and 115 can be integrated to form a single fuse set 150. For example, if the fuse set 150 is used in a DRAM device receiving 8 block selection signals, then the fuse 110 can have the first and second cutting regions 113 and 115, whereby the fuse set 150 can be formed by four fuses 110 instead of eight fuses.

The fuse set 150 includes the plurality of fuses 110, wherein the selected fuse 110 can be oriented at an angle of approximately 180° (degrees) relative to the fuse 110 adjacent to the selected fuse 110. When the fuse set 150 is formed by four fuses 110, for example, the first and second cutting regions 113 and 115 of the fuse 110 disposed in an odd position can face toward an upper side of the fuse set 150, and the first and second cutting regions 113 and 115 of the fuse 110 disposed in an even position can face toward a lower side of the fuse set 150. Accordingly, the first and second cutting regions 113 and 115 of the fuse 110 disposed on the even position can be disposed between the main fuses 111 of the plurality of fuses 110 disposed on the odd position.

In FIG. 3, the adjacent fuses 110 forming the fuse set 150 can be spaced apart from each other by the laser alignment tolerance D over an entire area of the fuse 110. Here, the adjacent fuses 110 can have substantially parallel first and second cutting regions 113 and 115, and main fuses 111. In addition, the branch-off region of the adjacent fuses 110, which correspond to the predetermined angle α°, can correspond (or be disposed next to) the bending section X.

In FIG. 3, fuse cutting areas C to which the laser beam is radiated can correspond to portions of the first and second cutting regions 113 and 115.

In FIG. 3, the overall length of the fuse set 150 is approximately 5D. Here, the length denotes a length of a long axis of the fuse set 150. Accordingly, the length of the fuse set 150 can be significantly reduced by about 40%.

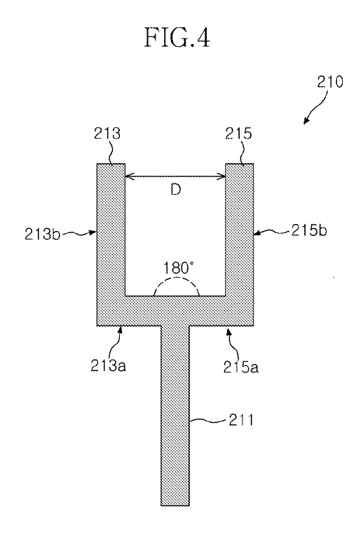

FIG. 4 is a plan view of another exemplary fuse according to another embodiment. In FIG. 4, a fuse 210 can be configured to include a main fuse region 211 and first and second cutting regions 213 and 215. In addition, the first and second cutting regions 213 and 215 can have a bending section X, and can be divided into first and second branch regions 213a and 215a and first and second substantially parallel regions 213b and 215b, respectively, at the bending section X.

The first and second branch regions 213a and 215a can be formed having a separation angle of about 180° (degrees), and the first and second parallel regions 213b and 215b can extend substantially parallel to each other. The first and second branch regions 213a and 215a of the fuse 210 can be substantially perpendicular to the first and second parallel regions 213b and 215b, wherein the first and second parallel regions 213b and 215b can be spaced apart from each other while maintaining the laser alignment tolerance D therebetween. Accordingly, the first and second branch regions 213a and 215a can have a length shorter than lengths of the first and second branch regions 113a and 115a of the fuse 110 (in FIGS. 2 and 3) such that the interval D between the first and second parallel regions 213b and 215b can be maintained.

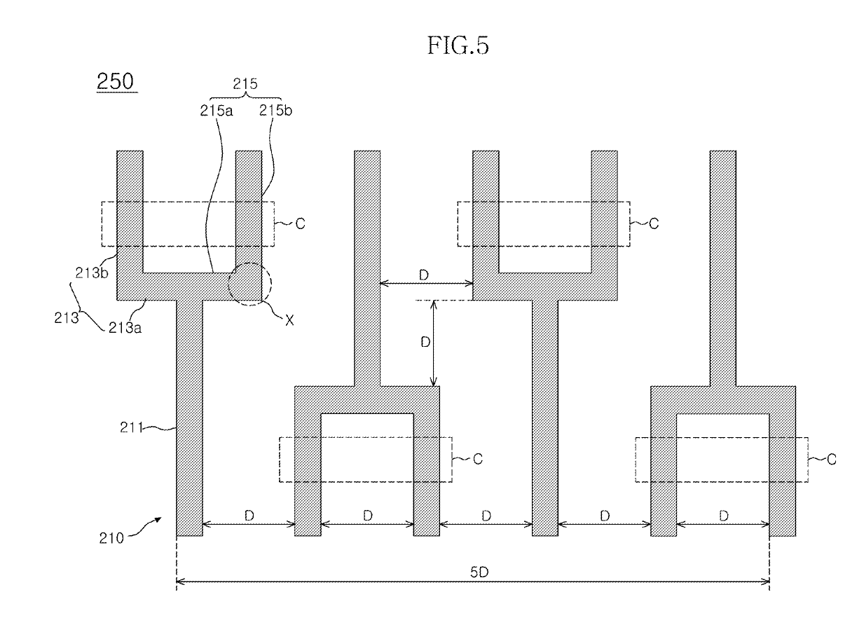

FIG. 5 is a plan view of another exemplary fuse set including the fuse of FIG. 4 according to another embodiment. In FIG. 5, a plurality of fuses 210 can be integrated to form a single fuse set 250 in which adjacent fuses 210 can be inversely arranged at an angle of about 180° (degrees) with respect to each other. For example, in a DRAM, the fuse set 250 can include four fuses 210 to form the first and second cutting regions 213 and 215 corresponding to a number of block selection signals of single row information. In the fuse set 250, the first and second cutting regions 213 and 215 of the fuse 210 disposed in an odd position can face toward an upper side of the fuse set 250, and the first and second cutting regions 213 and 215 of the fuse 210 disposed in an even position can face toward a lower side of the fuse set 250. Accordingly, the first and second cutting regions 213 and 215 of the fuse 210 disposed on the even position can be disposed between the main fuse regions 211 of the fuses 210 disposed on the odd position.

Accordingly, the adjacent fuses 210 can be spaced apart from each other by the laser alignment tolerance D over an entire area of the fuse 210. Here, the fuse cutting area C to which the laser beam is radiated can correspond to portions of the first and second cutting regions 213 and 215.

In FIG. 5, the overall length of the fuse set 250 is approximately 5β. Here, the length denotes a length of a long axis of the fuse set 250. Accordingly, the length of the fuse set 250 can be significantly reduced by about 40%.

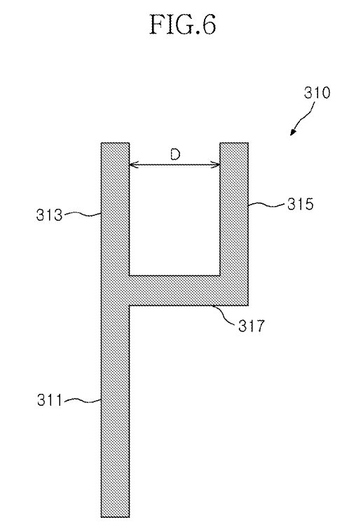

FIG. 6 is a plan view of another exemplary fuse according to another embodiment. In FIG. 6, the fuse 310 can be configured to include a main fuse region 311 and first and second cutting regions 313 and 315. The first and second cutting regions 313 and 315 can be spaced apart from each other by a laser alignment tolerance D. For example, the first cutting region 313 can extend from the main fuse region 311 in a substantially straight line configuration and the second cutting region 315 can be connected to the main fuse region 311 through a connection region 317. Here, the first cutting region 313 and the main fuse region 311 can be continuously connected to each other in a substantially straight line configuration while maintaining substantially the same line width. The connection region 317 can extend substantially perpendicularly to an extension direction of the first and second cutting regions 313 and 315.

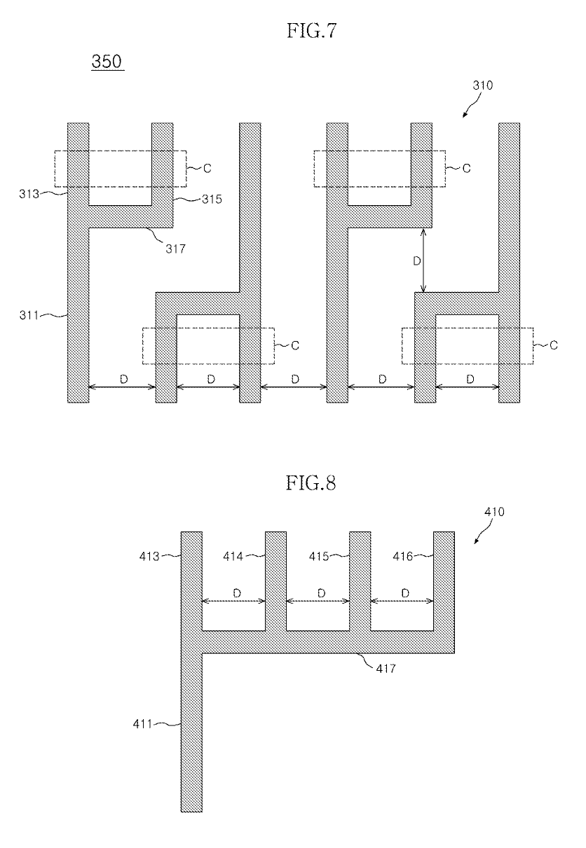

FIG. 7 is a plan view of another exemplary fuse set including the fuse of FIG. 6 according to another embodiment. In FIG. 7, a plurality of fuses 310 can be integrated to form a single fuse set 350. In the fuse set 350, the selected fuse 310 can be invertedly arranged with respect to the fuse 310 adjacent to the selected fuse 310 at an angle of about 180° (degrees). For example, four fuses 310 can be provided in a single fuse set 350 such that 8 of the first and second cutting regions 313 and 315 can be formed in the fuse set 350. In addition, the second cutting regions 315 of adjacent pairs of the fuse 310 can be substantially collinear.

In FIG. 7, the adjacent fuses 310 can be spaced apart from each other by a laser alignment tolerance D over an entire area of the fuses 310. For example, an interval between adjacent connection regions 317 can be ensured by the laser alignment tolerance D.

In FIG. 7, the overall length of the fuse set 350 is approximately 5D. Here, the length denotes a length of a long axis of the fuse set 350. Accordingly, the length of the fuse set 350 can be significantly reduced by about 40%.

FIG. 8 is a plan view of another exemplary fuse according to another embodiment. In FIG. 8, the fuse 410 can be configured to include a main fuse region 410 and four cutting regions 413, 414, 415, and 416. Here, the cutting regions 413, 414, 415, and 416 can extend substantially parallel to each other, and can be spaced apart from each other by a laser alignment tolerance D. For example, the first cutting region 413 can extend from the main fuse region 411 in a straight line configuration, wherein the four cutting regions 413, 414, 415, and 416 can be interconnected to each other through a connection region 417. The connection region 417 can extend substantially perpendicular to the four cutting regions 413, 414, 415, and 416.

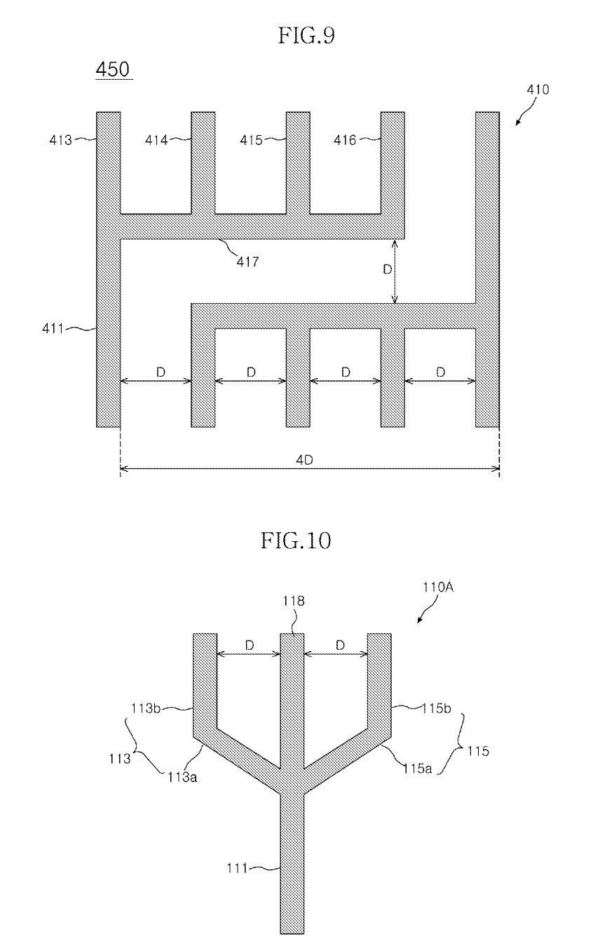

FIG. 9 is a plan view of another exemplary fuse set including the fuse of FIG. 8 according to another embodiment. In FIG. 9, two fuses 410, each including the four cutting regions 413, 414, 415, and 416, can be integrated to form a single fuse set 450.

In FIG. 9, a pair of fuse sets 450 including the four cutting regions 413, 414, 415, and 416 can be arranged substantially symmetrically to each other while forming an angle of about 180° (degrees) therebetween. Here, adjacent fuses 410 can be spaced apart from each other by a laser alignment tolerance D over an entire area of the fuses 410. Accordingly, an interval between adjacent connection regions 417 can be ensured by the laser alignment tolerance D. In addition, the cutting regions 414, 415, and 416 of adjacent pairs of the fuses 410 can be substantially collinear.

In FIG. 9, the overall length of the fuse set 450 is approximately 4D. Here, the length denotes a length of a long axis of the fuse set 450. Accordingly, the length of the fuse set 450 can be reduced by about 70%.

FIG. 10 is a plan view of another exemplary fuse according to another embodiment. In FIG. 10, a third cutting region 118 can be provided between the first and second cutting regions 113 and 115 of the fuse 110 (in FIG. 2) at a branch section where each of the first, second, and third cutting regions 113, 115, and 118 converge. Here, the third cutting region 118 can continuously extend from an end of the main fuse region 111 in a straight line configuration. The first cutting region 113 can be spaced apart from the third cutting region 118 by a laser alignment tolerance D, and the second cutting region 115 can be spaced apart from the third cutting region 118 by the laser alignment tolerance D.

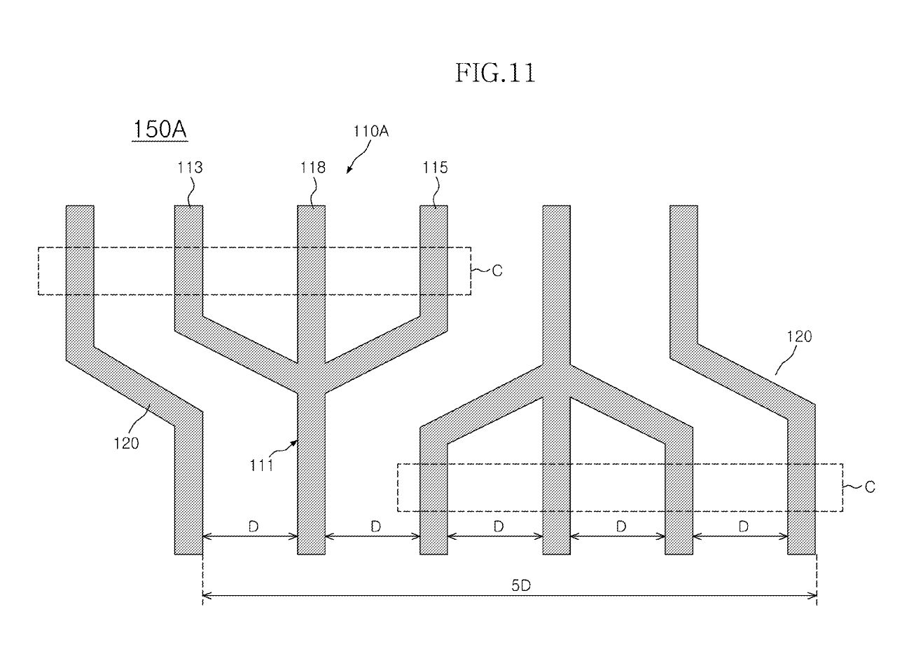

FIG. 11 is a plan view of another exemplary fuse set including the fuse of FIG. 10 according to another embodiment. In FIG. 11, a fuse 110A can be configured to including the three cutting regions 113, 115, and 118 to form a single fuse set 150A together with two single fuses 120. Here, the single fuse 120 can represent a fuse having a single cutting region. For example, if the single fuse set 150A must have 8 fuse cutting regions when the fuse set 150A is formed by the fuse 110A having three cutting regions 113, 115, and 118, then two single fuses 120 are included.

In FIG. 11, the fuse set 150A includes a pair of fuses 110A, which are inversely disposed with respect to each other at an angle of about 180° (degrees), in which the fuse 110A includes three cutting regions 113, 115, and 118, and the single fuse 120 is spaced apart from an outer side of the fuses 110A by a laser alignment tolerance D over an entire are of the fuses 110A. Since the single fuse 120 is spaced apart from the fuse 110A by the laser alignment tolerance D over the entire area of the fuse 110A and arranged in parallel to each other, the single fuse 120 must have at least two bending regions, similarly to the fuse 110A. In addition, the branch section of adjacent fuse 110A can be substantially aligned.

In FIG. 11, the overall length of the fuse set 150A is approximately 5D. Here, the length denotes a length of a long axis of the fuse set 150A. Accordingly, the length of the fuse set 150A can be significantly reduced by about 40%.

Alternatively, the fuses 110A can be alternatingly provided with the single fuses 120 to form the fuse set.

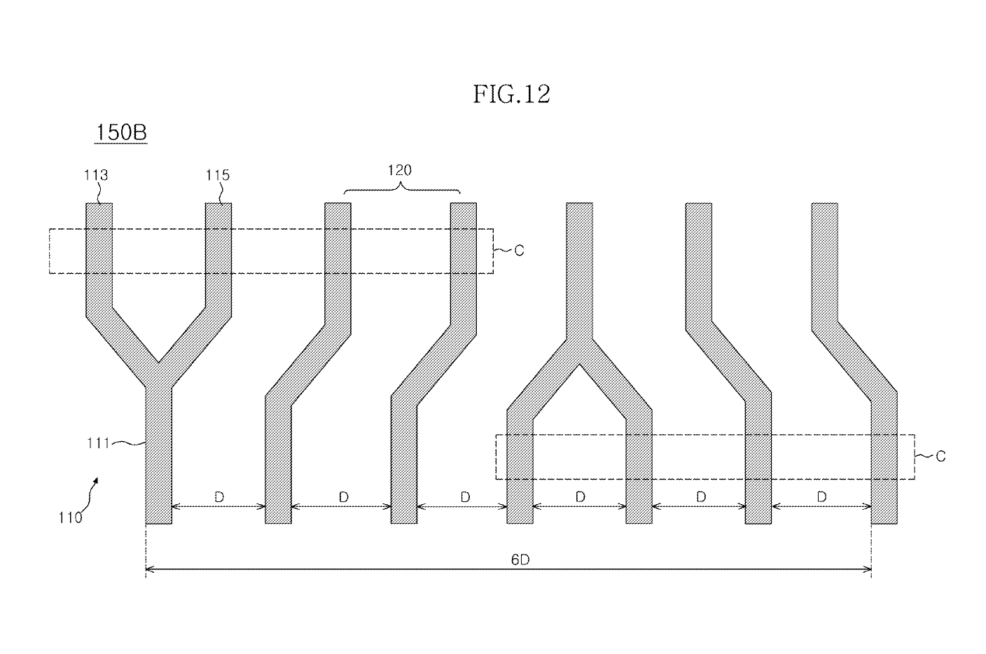

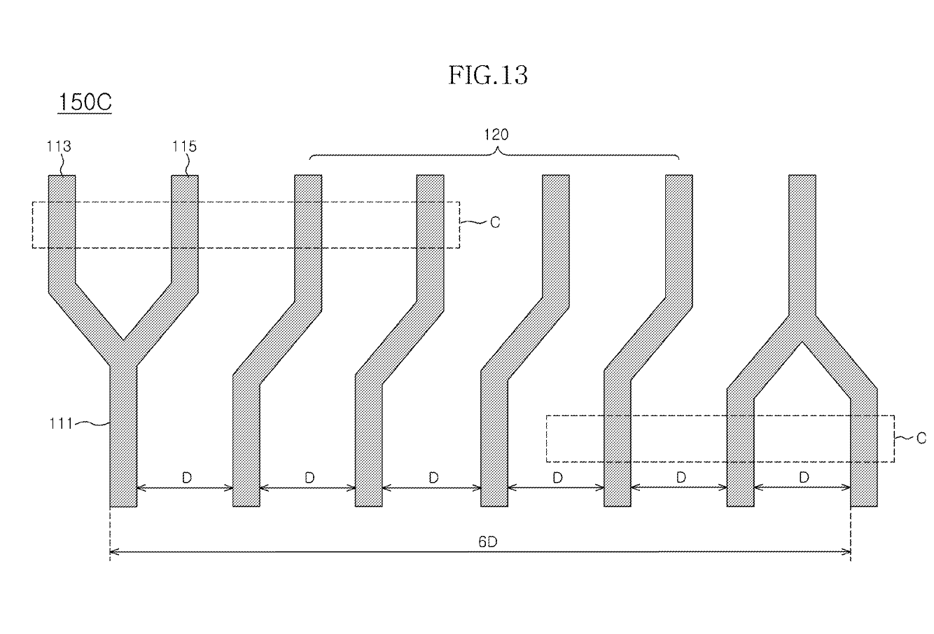

FIGS. 12 and 13 are plan views of exemplary fuses and cutting regions according to different embodiments. In FIGS. 12 and 13, fuse sets 150B and 150C can be configured to include a pair of fuses 110 each having first and second cutting regions 113 and 115 and a single fuse 120 disposed between the fuses 110. The fuses 110 can be inversely arranged with respect to each other at an angle of about 180° (degrees) and two of the single fuses 120 or four of the single fuses 120 may be arranged between the fuses 110.

In FIGS. 12 and 13, an interval between the fuse 110 having the first and second cutting regions 113 and 115 and the single fuse 120 adjacent to the fuse 110 can correspond to a laser alignment tolerance D. Here, for example, the single fuse 120 can be substantially parallel to a contour of the fuse 110.

In FIGS. 12 and 13, the overall length of the fuse set 150B is approximately 6D. Here, the length denotes a length of a long axis of the fuse set 150B. Accordingly, the length of the fuse set 150B can be significantly reduced. Although a single fuse set 150B is shown to include 8 fuse cutting regions, a total number of the fuse cutting regions can be increased or decreased.

Accordingly, a fuse can have at least two cutting regions, and a plurality of the fuses can be arranged substantially symmetrically to each other. Thus, an area for the fuse set can be significantly reduced compared to a fuse having a single cutting region. As a result, an area for the fuse set can be reduced in proportion to the integration degree of the semiconductor integrated circuit.

While certain embodiments have been described above, it will be understood that the embodiments described are by way of example only. Accordingly, the device and methods described herein should not be limited based on the described embodiments. Rather, the device and methods described herein should only be limited in light of the claims that follow when taken in conjunction with the above description and accompanying drawings.

What is claimed is:

1. A fuse, comprising:
a main fuse region; and
a plurality of cutting regions extend from the main fuse region.

2. The fuse of claim 1, wherein the plurality of cutting regions are spaced apart from each other by a laser alignment tolerance.

3. The fuse of claim 1, wherein each of the plurality of cutting regions includes:
a first branch region and a second branch region branching off from the main fuse region at a predetermined angle; and
a first parallel region and a second parallel region extend from the first and second branch regions, respectively, substantially parallel to each other.

4. The fuse of claim 3, wherein the first parallel region is spaced apart from the second parallel region by the laser alignment tolerance.

5. The fuse of claim 3, wherein the first and second branch regions branch-off from the main fuse region while forming an angle of about 180° (degrees) therebetween.

6. The fuse of claim 3, further comprising a third parallel region that extends from the main fuse region in a straight line configuration between the first and second parallel regions.

7. The fuse of claim 6, wherein the first parallel region is spaced apart from the third parallel region by the laser alignment tolerance.

8. The fuse of claim 7, wherein the second parallel region is spaced apart from the third parallel region by the laser alignment tolerance.

9. The fuse of claim 1, wherein the plurality of cutting regions extend substantially parallel to each other.

10. The fuse of claim 9, wherein one of the plurality of cutting regions extends from the main fuse region in a straight line configuration.

11. The fuse of claim 10, further comprising a connection region connecting the main fuse region to the cutting region.

12. The fuse of claim 11, wherein the connection region is substantially perpendicular to an extension direction of the main fuse and the cutting region.

13. The fuse of claim 12, wherein the plurality of cutting regions are spaced apart from each other by the laser alignment tolerance.

14. A fuse set, comprising:
a plurality of first fuses, each including a main fuse region and a plurality of cutting regions extending from the main fuse region,
wherein adjacent ones of the plurality of first fuse are invertedly turned about 180° (degrees) with respect to each other while maintaining a predetermined interval therebetween.

15. The fuse set of claim 14, wherein the adjacent ones of the plurality of first fuses are spaced apart from each other over an entire area of the plurality of first fuses by a laser alignment tolerance.

16. The fuse set of claim 14, wherein each of the plurality of cutting regions of the fuse includes:
a first branch region and a second branch region branching-off from the main fuse region at a predetermined angle; and
a first parallel region and a second parallel region extending from the first and second branch regions, respectively, substantially parallel to each other.

17. The fuse set of claim 16, wherein the first parallel region is spaced apart from the second parallel region by a laser alignment tolerance.

18. The fuse set of claim 16, wherein the first branch region and the second branch region have an angle of about 180° (degrees) therebetween.

19. The fuse set of claim 16, further comprising a third parallel region that extends from the main fuse region in a straight line configuration between the first and second parallel regions.

20. The fuse set of claim 19, wherein the first parallel region is spaced apart from the third parallel region by the laser alignment tolerance.

21. The fuse set of claim 20, wherein the second parallel region is spaced apart from the third parallel region by the laser alignment tolerance.

22. The fuse set of claim 14, wherein the plurality of cutting regions extend substantially parallel to each other.

23. The fuse set of claim 22, wherein one of the plurality of cutting regions extends from the main fuse region in a straight line configuration.

24. The fuse set of claim 23, further comprising a connection region connecting the main fuse region to the plurality of cutting regions.

25. The fuse set of claim 24, wherein the connection region extends substantially perpendicular to the main fuse and the cutting region.

26. The fuse set of claim 23, wherein the plurality of cutting regions are spaced apart from each other by a laser alignment tolerance.

27. The fuse set of claim 14, wherein the plurality of first fuses are consecutively arranged such that a number of the plurality of cutting regions correspond to a number of block selection signals of a semiconductor memory device.

28. The fuse set of claim 27, further comprising a second fuse having a single cutting region disposed between the plurality of first fuses.

29. The fuse set of claim 28, wherein the single cutting region of the second fuse corresponds to the number of the block selection signals.

30. The fuse set of claim 28, wherein the second fuse is spaced apart from the plurality of first fuses over an entire area of the plurality of first fuses.

31. The fuse set of claim 28, further comprising a plurality of second fuses, each of the plurality of second fuses having a single cutting region and being disposed between the plurality of first fuses.
